(19) United States
(12) Patent Application Publication
(10) Pub. No.: US 2024/0278285 A1
(43) Pub. Date: Aug. 22, 2024

(54) SHEAR WAVE MODE PIEZOELECTRIC RESONATOR

(71) Applicant: BIOMENSIO LTD, Tampere (FI)

(72) Inventor: Jyrki KAITILA, Kauniainen (FI)

(21) Appl. No.: 18/686,314

(22) PCT Filed: Aug. 24, 2022
(86) PCT No.: PCT/FI2022/050545

§ 371 Date: Feb. 23, 2024

(30) Foreign Application Priority Data
Aug. 25, 2021 (FI) 20215893

(51) Int. Cl. B06B 1/06; B81B 1/00; B81C 1/00; H10N 30/076; H10N 30/853; H10N 30/88

(52) U.S. Cl. CPC B06B 1/0659; B81B 1/002; B81C 1/00071; H10N 30/076; H10N 30/853; H10N 30/88; B81B 2201/0271; B81B 2201/05; B81B 2203/0338; B81C 2201/0133

(57) ABSTRACT

According to an aspect, there is provided a structure for a thin-film bulk acoustic resonator. The structure comprises a substrate (101) comprising a cavity (104) having at least one slanted flat surface (103) facing away from the cavity and a piezoelectric bulk material layer (102) deposited on said at least one slanted flat surface.

### TECHNICAL FIELD

The embodiments relate to piezoelectric resonators.

### BACKGROUND

Piezoelectric resonators, that is, electric resonators based on piezoelectric materials, have found use in various applications such as in sensors and radio frequency (RF) filters. One type of piezoelectric resonator which has seen considerable commercial interest is the so-called thin-film bulk acoustic resonator (FBAR) which comprises a piezoelectric material (typically AlN, ZnO or Sc_{X}Al_{1-X}N) manufactured using thin film manufacturing methods between two conductive (metallic) electrodes.

In some applications such as sensing and actuation, it is often desirable to excite specifically the thickness shear wave mode of the piezoelectric film of the thin-film bulk acoustic resonator. In the shear wave mode, the motion of the piezoelectric film is perpendicular to the direction of propagation of the wave with no local change of volume. It is well-known that, for example, a thin film of ZnO with c-axis of the crystal structure (crystalline z-axis) tilted at a particular angle relative to the surface of the substrate (roughly 39°) results in optimal coupling to the shear wave mode in the thin film of ZnO while simultaneously minimizing coupling to the longitudinal wave mode. Therefore, it would be beneficial for many applications if the piezoelectric material forming the thin film could be deposited onto the substrate so that the piezoelectric crystals would be oriented in said pre-defined regular manner. This may be achieved, for example, by inclining the wafer onto which the thin film is to be deposited relative to the sputtering target in the sputtering setup or introducing inclined blinds or lamels to the sputtering setup for guiding the sputtered particles. However, both of said solutions require some sort of modification to the sputtering tool. In other words, the manufacturing of the piezoelectric film having an inclined crystal is not possible with a standard sputtering setup.

### BRIEF DESCRIPTION

According to an aspect, there is provided the subject matter of the independent claims. Embodiments are defined in the dependent claims.

One or more examples of implementations are set forth in more detail in the accompanying drawings and the description below. Other features will be apparent from the description and drawings, and from the claims.

Some embodiments provide a structure for a thin-film bulk acoustic resonator, a thin-film bulk acoustic resonator and a method for manufacturing a thin-film bulk acoustic resonator.

### BRIEF DESCRIPTION OF DRAWINGS

In the following, exemplary embodiments will be described with reference to the attached drawings, in which

FIGS. 1A and 1B illustrate an exemplary structure for a thin-film bulk acoustic resonator according to embodiments from the side in a cross-sectional view and from above, respectively;

FIG. 1C illustrates the hexagonal wurtzite crystal structure;

FIGS. 2A and 2B illustrate an exemplary structure according to embodiments in a cross-sectional perspective view and in a partial cross-sectional side view, respectively;

FIG. 3 illustrates a sputtering process according to embodiments;

FIGS. 4A and 4B illustrate a thin-film bulk acoustic resonator according to embodiments and a method of manufacturing said thin-film bulk acoustic resonator, respectively; and

FIGS. 5A and 5B illustrate thin-film bulk acoustic resonators according to embodiments.

### DETAILED DESCRIPTION OF SOME EMBODIMENTS

The following embodiments are exemplary. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments.

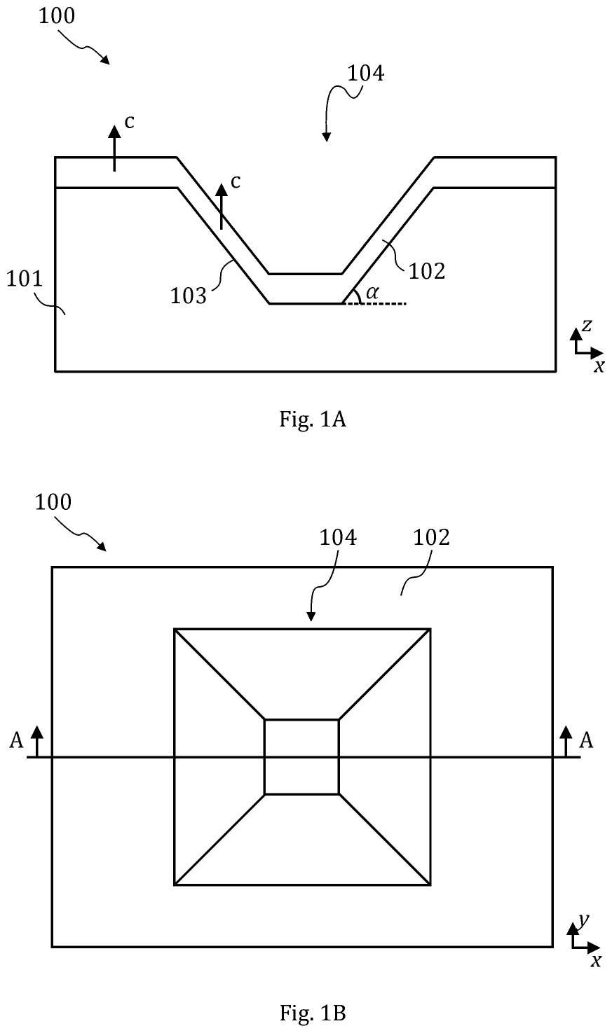

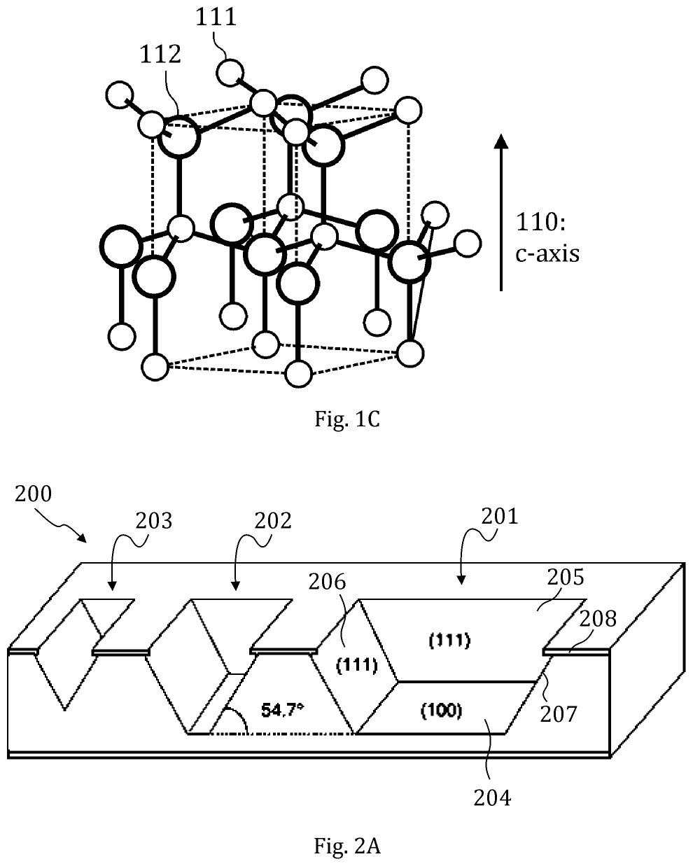

FIGS. 1A and 1B illustrate an exemplary structure 100 for a thin-film bulk acoustic resonator (equally called a thin-film bulk acoustic wave resonator) according to an embodiment. FIGS. 1A and 1B illustrate the same structure 100 from two different viewpoints: FIG. 1A shows a cross-sectional side view (or specifically a view of the central xz-plane) while FIG. 1B shows a view from the top (i.e., an xy-plane view). FIG. 1A corresponds to the cut-plane A visible in FIG. 1B.

Specifically, FIGS. 1A and 1B may illustrate a single unit cell of a periodic (or substantially periodic) or regular structure, that is, a structure periodic or regular in two orthogonal directions (x and y directions). A practical structure forming a part of thin-film bulk acoustic resonator according to embodiments may comprise N unit cells along the x-direction and M unit cells along the y-direction, where N and M may be any positive integers. In most practical scenarios, N and M are very large numbers. In other embodiments, the illustrated structure may form a part of a larger aperiodic structure.

Referring to FIGS. 1A and 1B, the structure 100 comprises two main elements: a substrate 101 and a piezoelectric bulk material layer 102 arranged or deposited on the substrate 101.

The material of the substrate 101 may be any conventional substrate material used in bulk acoustic wave (BAW) resonators or specifically in freestanding bulk acoustic (wave) resonators (FBARs). The substrate 101 may be made of silicon (Si). In some alternative embodiments, the substrate 101 may be a compound III-V or II-VI materials other than silicon such as gallium arsenide (GaAs), gallium nitride (GaN) or silicon carbide (SIC). The substrate 101 may form a wafer or a part thereof.

The substrate 101 comprises a cavity 104 (or, in general, at least one cavity) having at least one slanted (or equally inclined) flat surface 103 facing, at least in part, away from the cavity 104 (i.e., not facing only inwardly towards another surface of the cavity 104). A given slanted flat surface 103 may be defined to face, at least in part, away from the cavity 104 if it is possible to find a normal vector of said slanted flat surface 103 (originating from any point of said slanted flat surface 103) which fails to meet the cavity 104 (that is, fail to meet any bottom or side wall of the cavity 104 other than said slanted flat surface 103 from which it originated). Said at least one slanted flat surface 103 may be specifically arranged between an opening of the cavity 104 (which may be in-plane with the plane of the substrate 101) and a bottom of the cavity 104 (i.e., a bottom surface, edge or point of the cavity 104).

In the illustrated example, the cavity 104 has the shape of an upside-down (or inverted) right frustum with a square base and thus has four slanted flat surfaces facing away from the cavity. In general, the cavity 104 may have a shape of an upside-down (right) frustum or an upside-down (right) pyramid, where the bases of the frustum or the base of the pyramid may have a (regular) polygonal shape such as a rectangular or square shape. In general, said base(s) may have a (rotationally) symmetric shape.

Said at least one slanted flat surface 103 is slanted specifically relative to a plane of the substrate 101 (that is, the plane of the substrate 101 without the cavity 104), i.e., relative to the xy-plane. Said at least one slanted flat surface 103 forms a non-zero angle α with the plane of the substrate 101. Said angle α is defined here such that 0° would correspond to no slanting (i.e., to a conventional planar substrate). Said angle α has a value which is at least larger than 0° and smaller than 90° so that said at least one slanted flat surface 103 is, in fact, slanted and faces, at least in part, away from the cavity 104. Said angle α may have, e.g., a value between 25° and 55°, preferably between 32° and 50°. In general, the angle α may be selected so as to optimize the structure for thickness shear wave mode operation as will be discussed below in more detail.

In some embodiments where ZnO is used as the piezoelectric bulk material layer 102, the angle α may have, e.g., a value between 25° and 52°, preferably between 30° and 46°. In such embodiments, the angle α may be substantially 39º which corresponds substantially to the angle at which undesired coupling to the longitudinal wave mode is minimized.

In some embodiments where AlN is used as the piezoelectric bulk material layer 102, the angle α may have, e.g., a value between 25° and 55°, preferably between 33° and 51°. In such embodiments, the angle α may be substantially 47º which corresponds substantially to the angle at which undesired coupling to the longitudinal wave mode is minimized.

The cavity 104 may have dimensions in the micrometer range (i.e., at least 1 μm and smaller than 1 mm). Specifically, the (maximal) width of the cavity 104 (i.e., the largest dimension along the xy-plane) may be defined, e.g., to be within a range of 100-500 μm. The depth of the cavity 104 (along z-direction) may be defined, e.g., to be within a range of 50-300 μm.

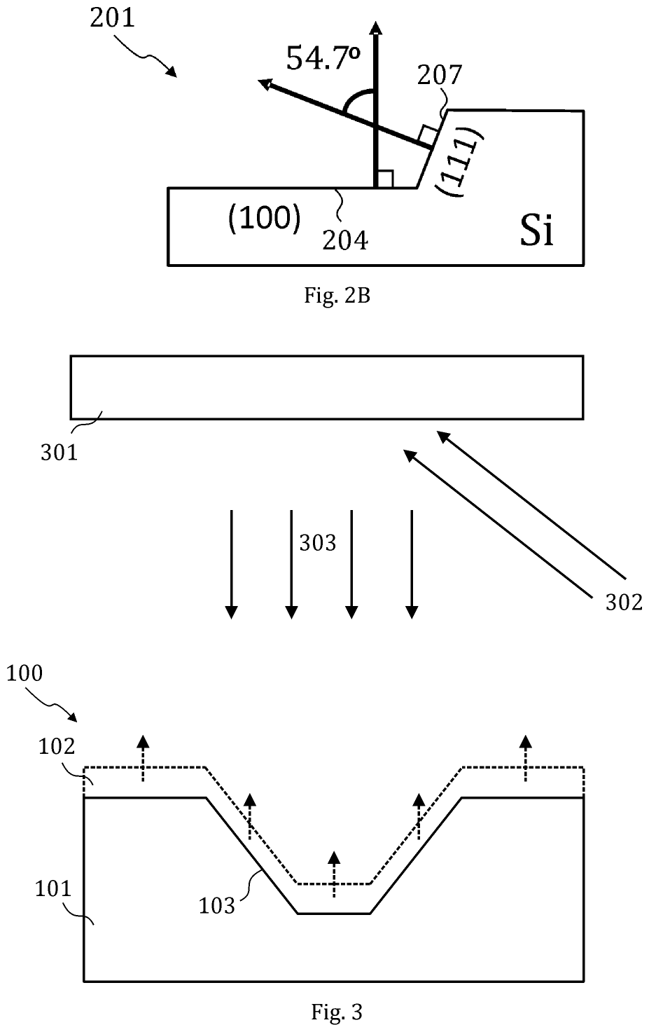

The manufacturing of cavities like the cavity 104 is discussed below in connection with FIGS. 2A and 2B.

The piezoelectric bulk material layer 102 is deposited at least on said at least one slanted flat surface 103 of the substrate 101 (or on a part thereof). In the illustrated example, the piezoelectric bulk material layer covers also non-slanted surfaces of the substrate 101 though this is not essential for desired operation.

The piezoelectric bulk material layer 102 may be made of a hexagonal crystal structure piezoelectric material supporting bulk acoustic wave propagation. Specifically, the piezoelectric bulk material layer 102 may be a thin film (of a hexagonal crystal structure piezoelectric material). The hexagonal crystal structure of the piezoelectric bulk material layer 102 may correspond specifically to the wurtzite crystal structure (being a specific example of a hexagonal crystal system). The piezoelectric bulk material layer 102 may be made of zinc oxide (ZnO), aluminum nitride (AlN) and/or and scandium aluminum nitride (Sc_{X}Al_{1-X}N), for example. The piezoelectric bulk material layer 102 may have a thickness of, e.g., 100 nm to 3000 nm (depending on, e.g., the desired operational frequency of the associated thin-film bulk acoustic resonator).

The piezoelectric bulk material layer 102 is assumed to have a c-axis which is non-perpendicular to said at least one slanted flat surface 103. Here and in the following, the c-axis may be defined, in general, as the (002) direction of a deposited crystal with a hexagonal wurtzite crystal structure. To further visualize the c-axis direction, FIG. 1C illustrates a representation of the wurtzite crystal structure with the c-axis direction being indicated with the arrow 110. In FIG. 1C, elements 111, 112 may correspond to Al & N or Zn & O, respectively. Dashed lines in FIG. 1C indicate the general hexagonal crystal structure.

Specifically, the c-axis of the piezoelectric bulk material layer 102 may be (substantially) perpendicular to a plane of the substrate 101, as shown in FIGS. 1A and 1B with an arrow originating from the slanted part of the piezoelectric bulk material layer 102. In other words, the c-axis of the crystal structure of the piezoelectric bulk material layer 102 forms a 90° angle with the planar surface of the substrate 101. This corresponds to a deposition angle (i.e., the angle at which the piezoelectric bulk material layer 102 was deposited) of 0°. Thus, any of the definitions for the value of the angle α according to embodiments may correspond to a value of the tilt angle of the c-axis relative to the plane of the substrate 101 (i.e., xy-plane in FIGS. 1A and 1B).

In other embodiments, the angle α and the tilt angle of the c-axis may be different. In such embodiments, any of the definitions for the value of the angle α according to embodiments provided above may apply, instead of the angle α, to a value of the tilt angle of the c-axis relative to the plane of the substrate 101. It is specifically the tilt angle of the c-axis relative to the plane of the substrate 101 (which is assumed to be parallel to a plane of the top and bottom electrodes used for excited the structure 100) which provides the desired operation of the structure 100, as will be described in the following paragraph.

As is well known in the art, different vibration modes may propagate in a piezoelectric bulk material layer of a BAW-based device. These vibration modes may comprise a longitudinal mode and/or one or more of two differently polarized shear modes. The longitudinal mode is characterized by compression and elongation in the direction of the propagation, whereas the shear modes consist of motion perpendicular to the direction of propagation with no local change of volume. Longitudinal and shear waves have different wave velocities. The propagation characteristics of these bulk wave modes depend on the material properties of the piezoelectric bulk material layer and propagation direction respective to the c-axis orientation. By tilting the c-axis of the crystal structure of the piezoelectric bulk material layer 102 relative to the (slanted) surface of the substrate in a pre-defined manner (i.e., setting a to have a certain pre-defined optimal value, e.g., 39° F. or ZnO), substantially optimal coupling to the shear wave mode in the piezoelectric bulk material layer 102 may be achieved while simultaneously minimizing coupling to the longitudinal wave mode. This type of operation is beneficial, for example, in fluid-based applications (e.g., sensors operating in liquid media such as chemical or biochemical sensors) as shear waves do not impart significant energy into fluids. Specifically, because shear waves exhibit a very low penetration depth into a liquid, a device with pure or predominant shear modes can operate in liquids without significant radiation losses (in contrast with longitudinal waves, which can be radiated in liquid and exhibit significant propagation losses).

It should be noted that the c-axis tilt relative to a normal (vector) of the at least one slanted flat surface 103 may correspond here specifically to the aforementioned slanting angle α or at least is affected by it. Thus, by adjusting the slanting of said at least one slanted flat surface 103, said c-axis tilt and thus coupling to the longitudinal and shear wave modes may be controlled without changing the deposition angle.

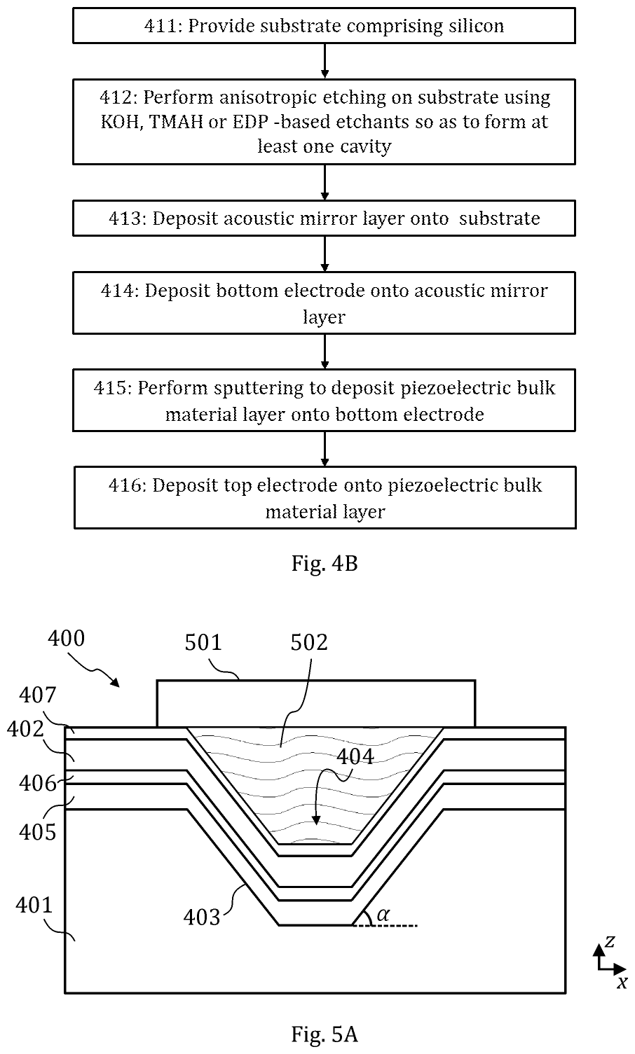

It should be noted that FIGS. 1A and 1B provide a simplistic presentation of a structure 100 according to embodiments. One or more further layers or elements conventionally used in FBARs may be included in said structure 100. The structure 100 may at least comprise top and bottom electrodes for exciting bulk acoustic waves in the structure 100. The piezoelectric bulk material layer 102 of the structure 100 may be deposited at least partially between said top and bottom electrodes. The top and bottom electrodes may be specifically arranged to conform to the shape of the substrate 101 (i.e., they may follow the shape of the cavity 104) so that c-axis forms said angle α also with the electric field excited by the top and bottom electrodes. This way the shear wave mode may be excited in an optimal manner with said top and bottom electrodes. The top and bottom electrodes may be arranged at least over the at least one slanted flat surface 103 or a part thereof. These possible further layers are discussed in more detail in connection with FIG. 4.

While only a single cavity 104 is shown in FIGS. 1A and 1B for simplicity of presentation, it should be appreciated that, in practical implementations, a plurality of cavities may be provided in the substrate 101 (i.e., in the wafer). Said plurality of cavities may have the same shape. Said plurality of cavities may be arranged in a regular grid (or lattice) such as a regular rectangular, square or hexagonal grid.

Anisotropic etching is an etching process where a crystalline structure is etched in an anisotropic manner so that different crystallographic orientations of the crystalline structure are etched at different rates. In single-crystal materials (e.g., in silicon wafers), this effect can allow very high anisotropy. Anisotropic etching refers typically to wet etching. Anisotropic etching may be considered fully or partly anisotropic depending on whether the etching occurs (substantially) only for a single crystal orientation (i.e., in practice, the etching rate for a certain crystal orientation one or several orders of magnitude larger than for other crystal orientations) or for multiple crystal orientations though at different rates. Thanks to the different etching rates for different crystallographic orientations (e.g., for crystal orientation (100) and (111)), anisotropic etching may be used for forming cavities having flat slanted surfaces as discussed in connection with FIGS. 1A and 1B in a substrate.

Several anisotropic wet etchants are available for silicon, many (if not all) of them hot aqueous caustics. For example, potassium hydroxide (KOH), tetramethylammonium hydroxide (TMAH) or ethylenediamine pyrocatechol (EDP, being an aqueous solution of ethylene diamine and pyrocatechol) may be used as wet etchants for silicon. For example, potassium hydroxide (KOH) displays an etch rate selectivity 400 times higher in (100) crystal directions than in (111) directions. EDP displays a (100)/(111) selectivity of 17×, does not etch silicon dioxide as KOH does, and also displays high selectivity between lightly doped and heavily boron-doped (p-type) silicon. Tetramethylammonium hydroxide (TMAH) presents a safer (less corrosive and less carcinogenic) alternative to EDP, with a 37× selectivity between (100) and (111) crystal planes in silicon.

The etching rate for a given crystallographic orientation is dependent, in addition to the type of the wet etchant, also on the concentration of the wet etchant. To provide an example of this behavior, the table shown below gives etching rates (with units μm/min at 70° C.) for different crystallographic orientations at different KOH concentrations. Normalized values relative to (110) crystal plane are given in parentheses. As can be seen from said table, by varying the KOH concentration, the etching rates for different crystallographic orientation change to a different extent (i.e., etch rate selectivity between different crystal directions such as (100) and (111) is changed). Specifically, it should be noted that etching rate is much higher for (100) crystal planes compared to (111) crystal planes. When the KOH concentration changes from 30% to 50%, the (100)/(111) selectivity is changed from 15.9 to 59.9. Thus, by tuning the KOH concentration (or equally TMAH or EDP concentration), different types of cavities (namely, cavities with slopes of different steepness) may be realized.

| Crystallographic | Rate at KOH | Rate at KOH | Rate at KOH |
|---|---|---|---|
| orientation | Concentration 30% | Concentration 40% | Concentration 50% |
| (100) | 0.797 (0.548) | 0.599 (0.463) | 0.539 (0.619) |
| (110) | 1.455 (1.000) | 1.294 (1.000) | 0.870 (1.000) |
| (210) | 1.561 (1.072) | 1.233 (0.953) | 0.959 (1.103) |
| (211) | 1.319 (0.906) | 0.950 (0.734) | 0.621 (0.714) |
| (221) | 0.714 (0.491) | 0.544 (0.420) | 0.322 (0.371) |
| (310) | 1.456 (1.000) | 1.088 (0.841) | 0.757 (0.871) |
| (311) | 1.436 (0.987) | 1.067 (0.824) | 0.746 (0.858) |
| (320) | 1.543 (1.060) | 1.287 (0.995) | 1.013 (1.165) |
| (331) | 1.160 (0.797) | 0.800 (0.619) | 0.489 (0.563) |
| (530) | 1.556 (1.069) | 1.280 (0.989) | 1.033 (1.188) |
| (540) | 1.512 (1.039) | 1.287 (0.994) | 0.914 (1.051) |
| (111) | 0.005 (0.004) | 0.009 (0.007) | 0.009 (0.010) |

Additionally or alternatively, the etching rate (and also etching rate selectivity, e.g., between crystal directions (100) and (111)) may be varied by changing the temperature. The below table provides an example of this behavior for 5% TMAH concentration. As can be seen from said table, by varying temperature from 60° C. to 90° C., the etch rate selectivity between crystal directions (100) and (111) for 5% TMAH etchant is changed from approximately 12.7 to 41.2.

| | Temperature | Crystallographic | Etching rate |
|---|---|---|---|
| Etchant | [° C.] | orientation | [μm/min] |
| 5% TMAH | 60 | (100) | 0.33 |
| 95% H₂O | 90 | (100) | 1.4 |
| | 60 | (110) | 0.64 |
| | 90 | (110) | 1.8 |
| | 60 | (111) | 0.026 |
| | 90 | (111) | 0.034 |

In summary, the etch rate selectivity between two crystal directions such as (100) and (111) is affected at least by the type of etchant, the concentration of the etchant in the etching solution and temperature.

The shape of the cavity may be controlled with an etch mask (e.g., made of silicon dioxide or nitride). The alignment and shape of the etch mask relative to the different crystal planes may also determine the etch profile (at least for certain crystal plane orientations of the used wafer such as (110)-oriented silicon wafer). Specifically, the alignment of the edges of the etch mask relative to the different crystal planes may determine the angle that the side wall forms with the plane of the substrate (i.e., the angle α). The etch mask may, at least in some embodiments, have at least one edge oriented along the desired crystal plane for creating at least one slanted surface corresponding to said crystal plane. In other embodiments, the etch mask may have at least one edge not oriented along any one single crystal plane for creating at least one slanted surface corresponding effectively to a combination of multiple crystal planes.

FIGS. 2A and 2B illustrate an exemplary substrate 200 for a thin-film bulk acoustic resonator according to an embodiment manufactured using anisotropic etching. FIG. 2A illustrates a substrate 200 in a cross-sectional perspective view while FIG. 2B shows a cross-sectional side view of one 201 of the cavities. In this example, the substrate 200 is specifically a (100) oriented silicon substrate (or wafer). Element 208 corresponds to an etch mask.

Specifically, FIG. 2A shows a substrate with three different cavities 201, 202, 203 of different shapes. All of said cavities 201, 202, 203 were formed simultaneously by wet etching the (100) oriented silicon substrate 200 using KOH. The bottom surfaces 204 of the cavities 202, 203 correspond to (100) crystal planes while the sidewalls 205, 206, 207 of the cavities 201, 202, 203 correspond to (111) crystal planes. The etching process terminates when the (111) crystal planes 205, 206, 207 of the sidewalls meet. In this example showing three cavities 201, 202, 203 of three different widths, the etching was effectively completed for the smallest cavity 203 as it has no bottom surface. Here, the (111) sidewalls 205, 206, 207 of the cavities 201, 202, 203 form a 54.7° angle (approximately) with the bottom surface 204 of the cavities 201, 202 (corresponding to the angle α discussed above). In other words, the (111) sidewalls 205, 206, 207 of the cavities 201, 202, 203 form a 35.3° angle with the normal (vector) of the plane of the substrate 200. It should be noted that the (111) plane is always developed (to a greater or lesser extent) as a sidewall of a concave structure in silicon wafer (of any crystallographic orientation), despite the shape of the etching mask.

While a (100) oriented silicon substrate was used in the example of FIGS. 2A and 2B, in other embodiments, a silicon substrate of some other orientation (e.g., (110)) may be employed. In general, the silicon substrate (i.e., the silicon wafer) may be oriented along a first crystal plane and said at least one slanted flat surface of the cavity may correspond to a second crystal plane different from the first crystal plane. This may be achieved by aligning at least one edge of the etch mask used in the etching with the second crystal plane. For example, by wet etching a (110) oriented silicon substrate using, e.g., KOH, TMAH or EDP, a cavity having at least one slanted surface with a slanting angle α of 35.3° (approximately) between the (111) sidewalls and the (110) bottom surface of the cavity may be realized. Such a solution may be especially beneficial to use with a ZnO piezoelectric bulk material layer due to the closeness of said slanting angle α to the angle at which the coupling to the longitudinal wave mode is minimized (namely, approx. 39°).

Moreover, by wet etching a (100) oriented silicon substrate using, e.g., KOH, TMAH or EDP, a cavity having at least one slanted surface with a slanting angle α of substantially 45° between the (110) sidewalls and the (100) bottom surface of the cavity may be realized if an etch mask having at least one edge aligned with the (110) crystal plane is used. Such a cavity may also have some surfaces (i.e., sidewalls) corresponding to (111) crystal planes (which may or may not be covered by the piezoelectric bulk material layer). Such a solution may be especially beneficial to use with an AlN piezoelectric bulk material layer due to the closeness of said slanting angle α to the angle at which the coupling to the longitudinal wave mode is minimized (namely, approx. 47°).

In other embodiments, wet etching using any of the aforementioned etchants (e.g., KOH, TMAH or EDP) may be employed for preparing cavities with at least one slanted surface which does not correspond to any single crystal plane but to a certain combination of a plurality of crystal planes. This may be achieved by not aligning the edge(s) of the etch mask with any particular one crystal plane.

In summary, by considering different silicon orientations as well as differently oriented and shaped etch masks and also the means for affecting etch rates for different crystal planes, a plurality of different slanting angles α may be implemented in the created cavities. Creation of a particular (arbitrary) slanting angle α is, thus, a matter of routing work and experimentation to a skilled person.

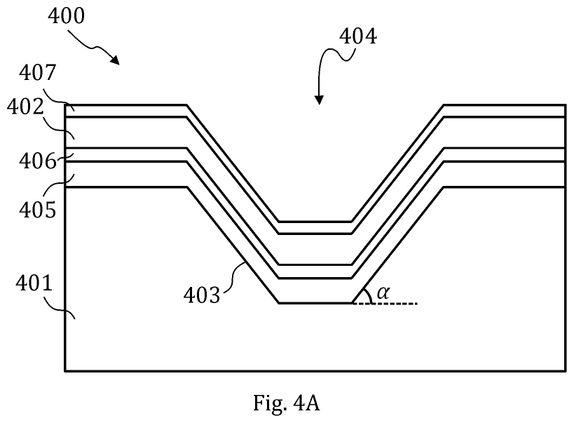

FIG. 3 illustrates a sputtering process for forming the piezoelectric bulk material layer 102 onto the substrate 101 with at least one cavity 104 (manufactured, e.g., using wet etching as described above). The formed structure corresponds here to the structure 100 of FIGS. 1A and 1B discussed above.

Referring to FIG. 3, the illustrated sputtering process may correspond, apart from the geometry of the substrate 101, to a sputtering process (or sputter deposition) as used commonly in thin film deposition manufacturing. Namely, the sputtering process may comprise initially placing the substrate 101 having a cavity 104 (or more likely, having a plurality of cavities) in a vacuum chamber containing an inert gas (e.g., argon). Then, highly energetic charged plasma particles 302 are made to collide with a sputtering target 301. The sputtering target 301 is made of the same material as discussed above for the piezoelectric bulk material layer 102 (e.g., ZnO, AlN or Sc_{X}Al_{1-X}N).

Said highly energetic charged plasma particles 302 may be created, e.g., using a magnetron. Such magnetron sputtering deposition uses magnets behind the negative cathode to trap electrons over the negatively charged target material 301 so they are not free to bombard the substrate 101, allowing for faster deposition rates. Magnetron sputtering may be (reactive) direct current (DC) magnetron sputtering or radio frequency (RF) magnetron sputtering. In the former case, the sputtering may be carried out in the presence of (oxygen) plasma. The collisions between the charged plasma particles 302 and the sputtering target 301 cause material 303 (i.e., atomic size particles) to be ejected from the sputtering target 301. These particles cross the vacuum chamber and are deposited as a thin film of material (i.e., the piezoelectric bulk material layer 102) on the surface of the substrate 101 to be coated.

During the sputtering, the sputtering target 301 may be oriented specifically substantially parallel to a plane of the substrate 101 (i.e., parallel to the non-slanted parts of the substrate 101) for producing a particle flux which is substantially orthogonal to the plane of the substrate. This results in a piezoelectric bulk material layer 102 having a c-axis which is, at least on average, perpendicular to the plane of the substrate 101 (both for the planar parts and slanted parts of the piezoelectric bulk material layer 102). In other words, due to the slanting of said at least one slanted flat surface 103 of the cavity, the substrate 101 does not have to be inclined relative to the sputtering target 301 in order to produce a piezoelectric bulk material layer 102 with a tilted c-axis.

Notably, the sputtering process of FIG. 3 is considerably simpler compared to known sputtering processes for producing a piezoelectric bulk material layer with a tilted c-axis. In said known processes, a cavity-free substrate onto which the thin film is to be deposited is inclined (or rotated) relative to the sputtering target in the sputtering setup or where a set of inclined blinds or lamels need to be introduced to the sputtering setup for guiding the sputtered particles to form a piezoelectric bulk material layer with the desired c-axis orientation. In contrast to said prior art sputtering processes, no changes to the well-established sputtering setup need to be carried out for manufacturing the structure according to embodiments. Namely, no additional dedicated tools need to be introduced to the basic sputtering setup (apart from potentially a standard collimator).

However, in some alternative embodiments, the sputtering target 301 may be inclined relative to the plane of the substrate 101 during the sputtering process and/or a set of inclined blinds or lamels may be introduced to the sputtering setup so as to provide means for controlling the deposition angle and thus enabling further finetuning of the tilt of the c-axis of the piezoelectric bulk material layer 102 (the tilt of the c-axis being predominantly defined by the slanting of the surfaces of the cavities in the substrate created using anisotropic etching). It should, however, be emphasized that such modifications to the sputtering setup are considered strictly optional.

As mentioned above, FIGS. 1A, 1B, 2A, 2B and 3 show only a simplified presentation of a structure for use in a thin-film bulk acoustic resonator according to embodiments (namely, showing only elements relevant for the main inventive concept according to embodiments). FIG. 4A illustrates a more detailed version of a thin-film bulk acoustic resonator 400 according to embodiments in a side view similar to FIG. 1A. The thin-film bulk acoustic resonator 400 is a so-called solidly mounted resonator (SMR) which one of the two basic types of thin-film bulk acoustic resonators (the other one being a free-standing resonator). The thin-film bulk acoustic resonator 400 may comprise the structure 100 of FIGS. 1A and 1B. FIG. 4B illustrate a process of manufacturing the thin-film bulk acoustic resonator 400 of FIG. 4A.

Referring to FIG. 4A, the thin-film bulk acoustic resonator 400 comprises a substrate 401 comprising a cavity 404 having at least one slanted flat surface 403 facing, at least in part, away from the cavity and a piezoelectric bulk material layer 402 deposited on said at least one slanted flat surface 403 (though not directly in this case but via layers 405, 406), similar to as discussed for the structure of FIGS. 1A and 1B. The elements 401 to 403 may correspond to elements 101 to 103 of FIGS. 1A and 1B.

Additionally, the thin-film bulk acoustic resonator 400 comprises a top electrode 407 and a bottom electrode 406. The bottom electrode is deposited (arranged) between the substrate 401 and the piezoelectric bulk material layer 402 while the top electrode 407 is deposited (or arranged) on the piezoelectric bulk material layer 402. In other words, the piezoelectric bulk material layer 402 is deposited or arranged (or “sandwiched”) at least partially between the top and bottom electrodes 407, 406. The top and bottom electrode layers 407, 406 may be formed, fully or partly, from an electrically conductive material such as aluminum or tungsten. The top and bottom electrodes 407, 406 may be used for exciting an electric field between them so as to excite a bulk acoustic wave (preferably, corresponding substantially to the shear wave mode) in the piezoelectric bulk material layer 402. The frequency of the bulk acoustic wave (i.e., of the associated mechanical oscillations) is dependent on any mass weighing upon the thin-film bulk acoustic resonator 400. In typical applications, said mass corresponds to a particular sample to be measured (i.e., an analyte). Thus, by measuring this frequency (or its change), various weight-dependent properties of a given sample may be deter-mined.

Moreover, the thin-film bulk acoustic resonator 400 comprises an acoustic mirror layer 405 (or equally an acoustic reflector layer) for providing acoustic isolation. The acoustic mirror layer 405 is deposited or arranged between the substrate 401 and the bottom electrode 406. The acoustic mirror layer 405 may be formed, for example, as a set of alternating thin layers of materials having different acoustic impedances, optionally embodied in a Bragg mirror. For example, the acoustic mirror layer 405 may comprise alternating high impedance layers (e.g., AlN layers) and low impedance layers (e.g., SiO₂ layers). The thickness of mirror materials may specifically be optimized to the quarter wavelength operation for maximum acoustic reflectivity. In some embodiments, the acoustic mirror layer 405 may be omitted.

In some embodiments, the thin-film bulk acoustic resonator 400 may also comprise one or more further layers not shown in FIG. 4A such as at least one seed layer and/or at least one adhesion layer (deposited on the substrate before any other layer) and/or at least one support layer (being, e.g., a dielectric layer) for providing structural support.

While in FIG. 4A the different layers 402, 405-407 of the thin-film bulk acoustic resonator 400 are shown completely covering the substrate 401, in other embodiments, said layers 402, 405-407 (or at least some of them) may cover at least or exclusively said at least one slanted flat surface 403 of the substrate 401 or a part of said at least one slanted flat surface 403 of the substrate 401.

Referring to FIG. 4B, the thin-film bulk acoustic resonator 400 of FIG. 4 may be formed by performing the following steps:
block 411: providing a substrate 401 comprising silicon (or other compound III-V or II-VI material such as GaAs, GaN or SiC,
block 412: forming at least one cavity 404 on the substrate 401, e.g., as discussed in connection with FIGS. 1A, 1B, 2A and/or 2B (for example, using anisotropic etching),
block 413: depositing the acoustic mirror layer 405 (directly) onto the substrate 401 having said at least one cavity 404,
block 414: depositing the bottom electrode 406 (directly) onto the acoustic mirror layer 405,
block 415: growing the piezoelectric bulk material layer 402 (directly) onto the bottom electrode 406 (and optionally, in part, onto the acoustic mirror layer 405), e.g., using sputtering as discussed in connection with FIG. 3 and
block 416: depositing the top electrode 406 (directly) onto the piezoelectric bulk material layer 402.
   Forming the at least one cavity in block 412 may specifically comprise at least performing anisotropic etching on the substrate using KOH, TMAH or EDP-based etchants so as to form at least one cavity, wherein each of said at least one cavity has at least one slanted flat surface facing, at least in part, away from that cavity. The growing of the piezoelectric bulk material layer in block 415 may correspond to performing sputtering to deposit a piezoelectric bulk material layer onto (i.e., on top of) said at least one slanted flat surface or a part thereof. During the sputtering, a sputtering target may be oriented substantially parallel to a plane of the substrate for producing a particle flux which is substantially orthogonal to the plane of the substrate, at least according to some embodiments.

In addition or alternative to the layers discussed in connection with FIG. 4, a spray or electroplated photoresist may be employed for coating the side walls of the cavity (or cavities) for enabling patterning. To give an example, AZ 4999 may be employed as a spray photoresist.

The thin-film bulk acoustic resonator 400 may be integrated with an integrated circuit. Said integrate circuit may be configured to feed the top and bottom electrodes 407, 406, i.e., to transmit signals to and/or receive signals from the top and bottom electrodes 407, 406. The integrated circuit may be specifically a read-out integrated circuit (ROIC), that is, an integrated circuit specifically used for reading detector(s) or sensor(s) of a particular type. The read-out integrated circuit may be configured, for example, to perform charge amplification (using a charge amplifier) for converting the charge output of the thin-film bulk acoustic resonator 400 to a voltage and/or filtering (e.g., bandpass or high-pass filtering). The read-out integrated circuit may comprise at least one output (or output port or terminal) for outputting the measured signal.

The integration of the thin-film bulk acoustic resonator 400 to the integrated circuit may be achieved using a variety of different electrical connection means. To give a simple example, wire bonding may be employed for connecting the thin-film bulk acoustic resonator 400 (or specifically the top and bottom electrodes 407, 406) to an input/output terminal and to the ground of an integrated circuit. Alternatively, through-silicon via(s) (TSVs) may be employed for forming said electrical connection. As the name implies, a TSV is a vertical electrical connection (or via) that passes completely through a silicon wafer or die.

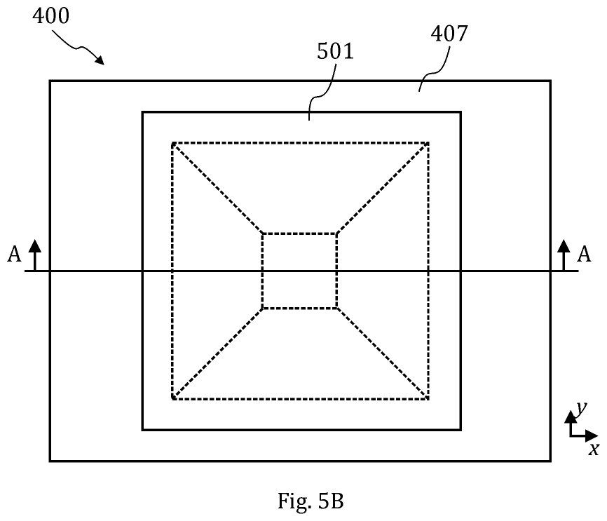

The thin-film bulk acoustic resonator 400 (with said integrated circuit) may be used, for example, as a sensor (or specifically a chemical or biochemical sensor) in fluid-based applications. In such applications, (micro)fluidic channel(s) may be formed in the at least one cavity 404 of the thin-film bulk acoustic resonator 400. FIGS. 5A and 5B illustrate the thin-film bulk acoustic resonator 400 of FIG. 4 with such a (micro)fluidic channel formed in the cavity 404. Specifically, FIG. 5A shows a cross-sectional side view (or specifically a view of the central xz-plane) while FIG. 5B shows a view from the top (i.e., an xy-plane view), similar to FIGS. 1A and 1B.

Referring to FIGS. 5A and 5B, the cavity 404 acting as a fluidic channel may comprise a fluidic sample 502. FIG. 5A corresponds to the cut-plane A visible in FIG. 5B. Said fluidic sample may comprise, e.g., at least one analyte which is made to react with at least one reagent (e.g., an antibody). The cavity 404 (and thus the formed fluidic channel 502) may be covered with closing or covering means 501 (e.g., a lid, a cover or a top) for closing the cavity 404 and thus preventing the fluidic sample 502 from escaping from the fluidic channel. Said closing or covering 501 may fully enclose said cavity 404. The closing or covering may be made of a liquid-impermeable (or water-impermeable) material.

Even though the invention has been described above with reference to examples according to the accompanying drawings, it is clear that the invention is not restricted thereto but it can be modified in several ways within the scope of the appended claims. Therefore, all words and expressions should be interpreted broadly and they are intended to illustrate, not to restrict, the embodiment. It will be obvious to a person skilled in the art that, as technology advances, the inventive concept can be implemented in various ways.

1. A structure for a thin-film bulk acoustic resonator comprising:
a substrate comprising at least one cavity having at least one slanted flat surface, wherein each of said at least one slanted flat surface faces, at least in part, away from a corresponding cavity; and
a piezoelectric bulk material layer deposited at least on said at least one slanted flat surface or a part thereof.

2. The structure of claim 1, wherein a first surface of said at least one slanted flat surface forms a first angle with a plane of the substrate, the first angle having a value between 25° and 55°, preferably between 32° and 50°.

3. The structure according to claim 1, wherein the piezoelectric bulk material layer exhibits hexagonal wurtzite crystal structure and has a c-axis which is non-perpendicular to said at least one slanted flat surface.

4. The structure according to claim 3, wherein the c-axis of the piezoelectric bulk material layer is substantially perpendicular to a plane of the substrate.

5. The structure according to claim 3, wherein the c-axis of the piezoelectric bulk material layer is tilted relative to a plane of the substrate by a second angle having a value between 25° and 55°, preferably between 32° and 50°.

6. The structure according to claim 1, wherein each of the at least one cavity has a shape of an upside-down frustum or an upside-down pyramid.

7. The structure resonator according to claim 1, wherein the substrate is a wafer oriented along a first crystal plane or a part thereof and said at least one slanted flat surface corresponds substantially to a second crystal plane different from the first crystal plane or to a combination of a plurality of second crystal planes different from the first crystal plane.

8. The structure according to claim 1, wherein the piezoelectric bulk material layer comprises one of ZnO, AlN and Sc_{X}Al_{1-X}N and/or the substrate comprises silicon.

9. A thin-film bulk acoustic resonator comprising:
the structure according to claim 1;
a bottom electrode deposited between the substrate and the piezoelectric bulk material layer of the structure; and
a top electrode deposited on the piezoelectric bulk material layer of the structure.

10. A thin-film bulk acoustic resonator comprising:
the structure according to claim 4;
a bottom electrode deposited between the substrate and the piezoelectric bulk material layer of the structure; and
a top electrode deposited on the piezoelectric bulk material layer of the structure, wherein the top and bottom electrodes are adapted to follow a shape of said at least one cavity for exciting a bulk acoustic wave in a slanted section of the piezoelectric bulk material layer.

11. The thin-film bulk acoustic resonator of claim 9, further comprising:
an acoustic mirror layer deposited between the substrate and the bottom electrode.

12. The thin-film bulk acoustic resonator according to claim 9, further comprising:
an integrated circuit for feeding the top and bottom electrodes; and
electrical connection means for electrically connecting the integrated circuit to the top and bottom electrodes.

13. The thin-film bulk acoustic resonator according to claim 9, further comprising:
liquid-impermeable means for closing the cavity.

14. A method of manufacturing comprising:
providing a substrate comprising silicon;
performing anisotropic etching on the substrate using potassium hydroxide, KOH, tetra-methyl ammonium hydroxide, TMAH or ethylenediamine pyrocatechol, EDP, -based etchants so as to form at least one cavity, wherein each of said at least one cavity has at least one slanted flat surface facing, at least in part, away from that cavity; and
performing sputtering to deposit a piezoelectric bulk material layer onto said at least one slanted flat surface or a part thereof.

15. The method of claim 14, wherein, during the sputtering, a sputtering target is oriented substantially parallel to a plane of the substrate for producing a particle flux which is substantially orthogonal to the plane of the substrate.

16. The method of claim 14, further comprising:
depositing, before the sputtering, an acoustic mirror layer onto the substrate;
depositing, before the sputtering, a bottom electrode onto the acoustic mirror layer; and
depositing, after the sputtering, a top electrode onto the piezoelectric bulk material layer.
